(19) United States
(12) Patent Application Publication
(10) Pub. No.: US 2003/0090880 A1
(43) Pub. Date: May 15, 2003

(54) Circuit board assembly with multiple cartridge slots

(75) Inventors: Shih-Chieh Wang, Taipei (TW); Chien-Lung Huang, Taipei (TW); Yen-Te Chiang, Taipei (TW); James Tseng, Shulin City (TW); Chu-Yang Hsu, Hsinchu (TW); Hsi-Hsing Hsu, Taoyuan (TW)

Correspondence Address: BRUCE H. TROXELL, SUITE 1404, 5205 LEESBURG PIKE, FALLS CHURCH, VA, 22041, US

(73) Assignee: High Tech Computer Corp.

(21) Appl. No.: 10/097,735

(22) Filed: Mar. 15, 2002

(30) Foreign Application Priority Data
Nov. 9, 2001 (TW) 90219317

(51) Int. Cl. H05K 1/14

(52) U.S. Cl. 361/736

(57) ABSTRACT

A circuit board assembly with multiple cartridge slots adapted for use in a casing of an electronic product includes a circuit board, at least one first cartridge slot and at least one second cartridge slot. The first cartridge slot is located on a first side of the circuit board. The second cartridge slot is located on a second side of the circuit board. Through mounting the cartridge slots to both sides of the circuit board, utilization space for circuit board design can be increased. Also, both sides of the circuit board can function as heat-dissipating space for facilitating steady operation of circuits and elements located on the circuit board.

### FIELD OF THE INVENTION

The present invention relates to a circuit board assembly with multiple cartridge slots, and more particularly to a printed circuit board that equips at least a cartridge slot in each surface side thereof.

### BACKGROUND OF THE INVENTION

Nowadays, most of electronic products have cartridge slots located on the printed circuit boards to receive external cartridges for loading software or expanding memory. Such a printed circuit board configuration is widely adapted for notebook computers, translators, personal digital assistant (PDA) or other the like electronic products.

FIG. 1 illustrates a conventional circuit board. Please note that, for clearly viewing the picture, electronic elements and support frames of the circuit board are omitted. The circuit board 1 includes a first side 100 and an opposite second side 200. The first side 100 has a built-in cartridge slot 11 for holding an external cartridge (not shown in the drawing). The cartridge slot 11 includes a slot opening 110 located to an edge of the circuit board 1 to facilitate building of the casing (not shown in the drawing) of the electronic product.

A growing demand upon increasing design versatility of the products has made the trend that additional cartridges for concurrently operation are practically required. In the art, conventional approaches to catch up this trend are categorized into three types (by taking concurrent operation of two cartridges as an example):

1. A built-in cartridge slot on the circuit board and an external cartridge (not shown in the drawing) coupling with a connection port of the circuit board: Such type of construction is usually adopted in notebook computers, in which a built-in optical disk drive and an external connecting 3½″ disk drive are provided.

2. Two sets of built-in cartridge slots installed on the same side of the circuit board but at different locations as shown in FIG. 2: These two cartridge slots 11a and 11b are located to two edges of a first side 100a of the circuit board 1a. Such type of construction is often adopted to All-In-One notebook computers, in which two disk drives are built in the same casing of a circuit board.

3. Two cartridge slots stacking at the same location of a circuit board.

Among these three categories, the first approach requires a lot of elements and is deemed as an interim design that is inconvenient to use.

The second approach, though, can achieve better utilization, yet it occupies a substantial surface space on the circuit board to accommodate two cartridge slots. It can be foreseen that this second approach may be easily adapted to some large-scale electronic products such as notebook computers. However, it is a big problem for most small-size electronic products (such as PDAs) that cannot provide sufficient space to accommodate additional slots.

The third approach can offer better device utilization in a limited installation space. Yet, stacking two cartridge slots may result in an inevitable product thickness and thus incur troubles in marketing.

In addition, aforesaid second and third approaches may have heat dissipation problem over the circuit board. For instance, as the circuit board 1a shown in FIG. 2, heat generated from the cartridges (not shown in the drawing) in the slots during operation is mostly dissipated over the first side 100a of the circuit board 1a, with less dissipated through the second side 200a. Under such an arrangement in large-size electronic products, enough space can be provided to install heat-radiating elements (such as cooling fins, air fans, cooling tubes, or the like) for overcoming the heat-dissipating problem. Nevertheless, for those small-size electronic products such as PDAs and translators that demand a slim size and a lightweight, squashing out additional space for accommodating additional heat-radiating elements is definitely not preferably.

### SUMMARY OF THE INVENTION

Accordingly, the primary object of the present invention is to provide a circuit board assembly with multiple cartridge slots that includes at least two cartridge slots mounted to both sides of the circuit board, so that both sides of the circuit board can be used as effective heat-radiating space to allow adjacent elements or circuits on the circuit board to operate steadily.

The circuit board assembly with multiple cartridge slots of the invention, which can be sandwiched within a casing of an electronic product, includes a first side and a second side opposite to the first side. The first side thereof has at least one first cartridge slot and the second side has at least one second cartridge slot.

In an embodiment of the invention, the first cartridge slot and the second cartridge slot are stacked together but spaced by the circuit board.

In an embodiment of the invention, the circuit board can be enclosed by a casing. Also, the first cartridge slot has a first slot opening, and the second cartridge slot has a second slot opening. Respectively, the casing provides a first opening and a second opening corresponding to the first slot opening and the second slot opening for facilitating retrieving operation of cartridges with respect to the first and the second cartridge slots. Preferably, the casing has an openable first dust-guarding lid and an openable second dust-guarding lid located respectively to the first opening and the second opening for covering the first slot opening of the first cartridge slot and the second slot opening of the second cartridge slot, respectively.

In an embodiment of the invention, the first cartridge slot and the second cartridge slot are stacked together but spaced by the circuit board, are housed in a casing, and have a common openable dust-guarding lid for shielding simultaneously the first opening and second opening on the casing corresponding to the first slot opening and the second slot opening, respective.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of a conventional circuit board;

FIG. 2 is a perspective view of a conventional circuit board with two cartridge slots;

FIG. 3 is a perspective view of an embodiment of the invention;

FIG. 4 is a perspective view of the invention according to FIG. 3 in use;

FIG. 5 is a perspective view of another embodiment of the invention; and

FIG. 6 is a perspective view of the invention according to FIG. 5 in use.

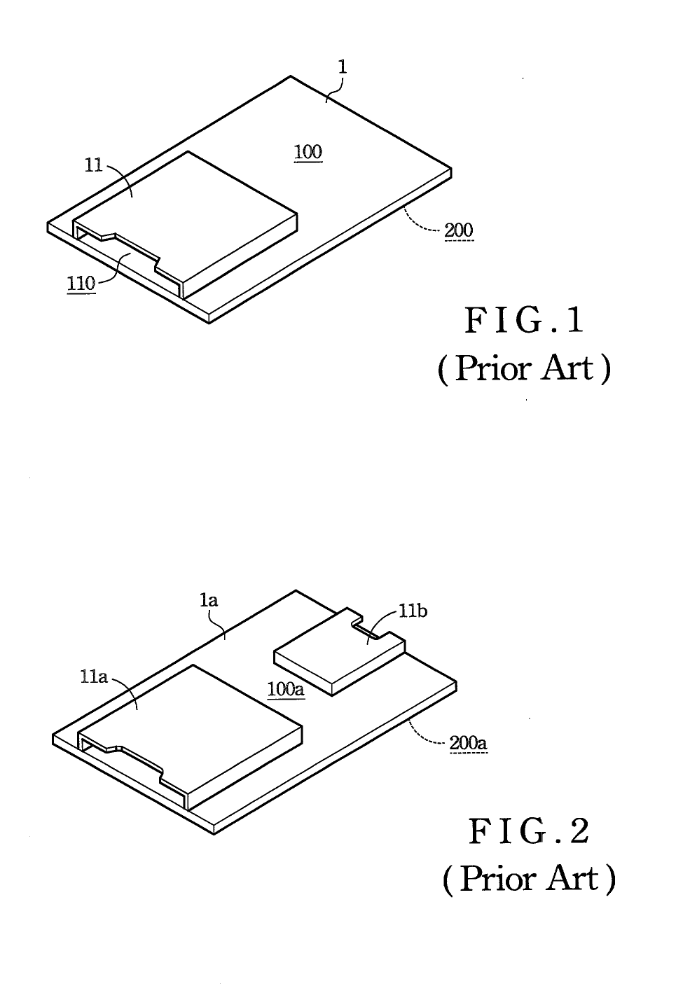

### DESCRIPTION OF THE PREFERRED EMBODIMENTS

In the following description, elements of similar function will be marked by similar numerals but affixed with a small English letter to make the description consistent.

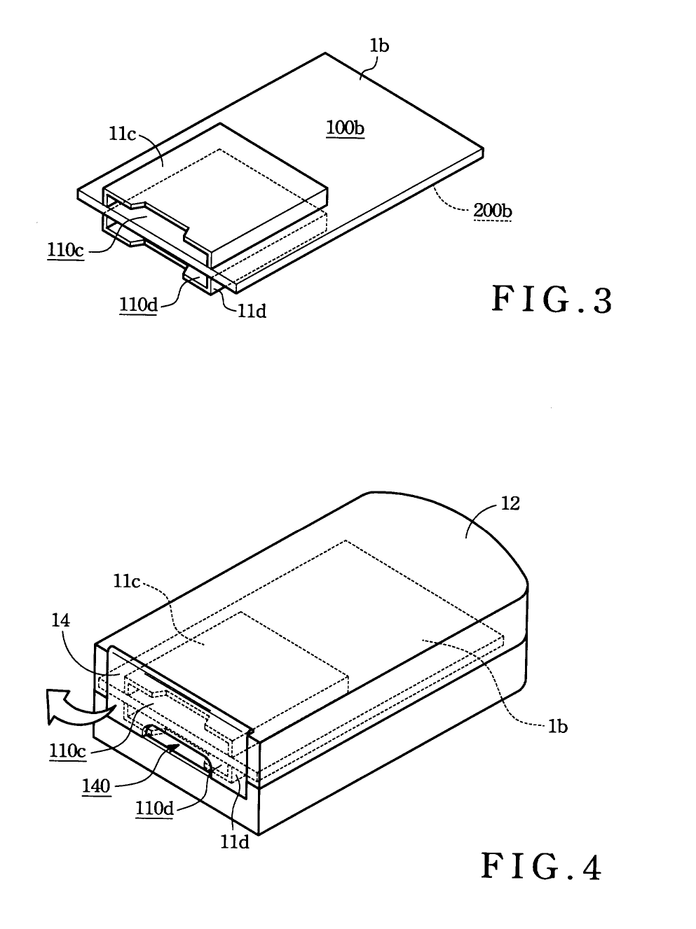

Referring now to FIG. 3 for a preferred embodiment of the invention, the circuit board assembly with multiple cartridge slots as shown includes a circuit board 1b that has at least a first cartridge slot 11c (one shown in the drawing) and at least a second cartridge slot lid (one shown in the drawing). The circuit board 1b has a first side 100b and a second side 200b opposite to the first side 100b. The first cartridge slot 11c is located on the first side 100b, and respectively the second cartridge slot 11d is located on the second side 200b. In this embodiment of FIG. 3, the first cartridge slot 11c and the second cartridge slot 11d are stacked at one end of the circuit board 1b and are spaced from each other by the circuit board 1b. The first cartridge slot 11c and the second cartridge slot lid can further have respectively a first slot opening 10c and a second slot opening 110d for receiving individual cartridges when in use.

Referring now to FIG. 4 for the circuit board assembly with multiple cartridge slots adopted for a device, the first cartridge slot 11c, the circuit board 1b and the second cartridge slot 11d are all housed in a casing 12 at one end thereof. The casing 12 provides a common opening 140 formed at one end corresponding to the first slot opening 110c and the second slot opening 110d for allowing cartridges' retrieving operations with the cartridge slots 11c and 11d. As shown in the drawing, an openable dust-guarding lid 14 may be deployed on casing 12 over the common opening 140 for shielding the first slot opening 110c and the second slot opening 110d.

Referring also to FIG. 4, when the invention is used in a device, heat dissipating means may be disposed on both sides of the circuit board 1b so as to form two independent radiating spaces with respect to both sides of the device. In contrast, conventional techniques (as shown in FIG. 2) have the cartridge slots 11a and 11b located on the same side 100a of the circuit board 1a and thus traps the heat source on a single side of the circuit board 1a (i.e., makes only one radiating space). In addition, the layout and configuration of the circuit board with cartridge slots provided by the invention can present designers more utilization space and installation allowance on the circuit board. Therefore, the invention is obviously superior to the prior art in view of heat dissipation and element allocation upon the concerned electronic product.

The dust-guarding lid 14 of the present invention can be an openable covering element. It may be a pivotal plate that can be flipped outwards. In other embodiments (not shown in the drawings), the lid 14 can also rotate pivotally inwards, slide sideward, or move at any other openable means known in the art.

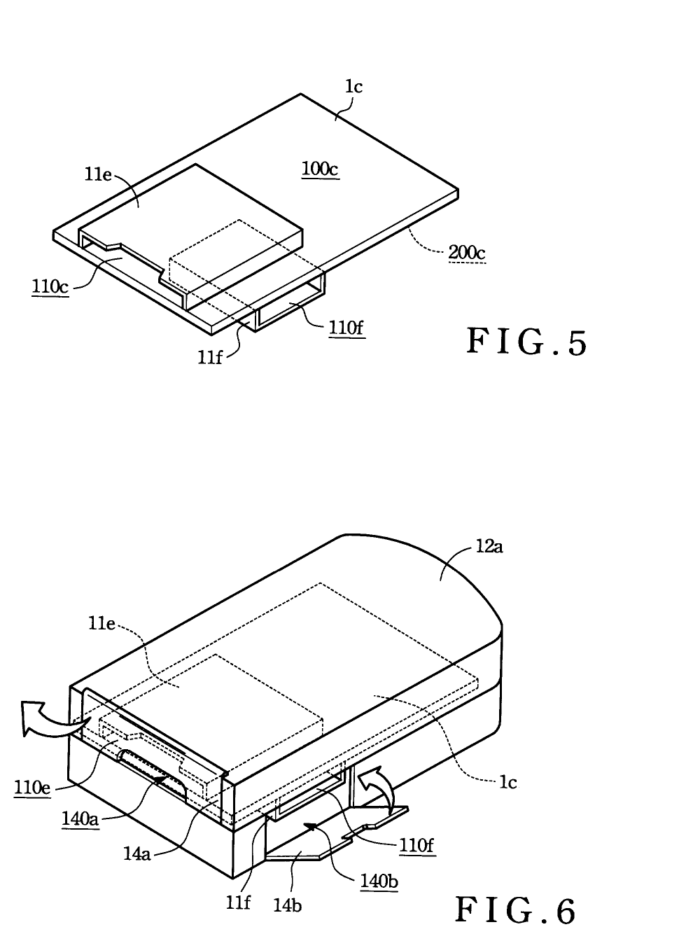

Referring now to FIG. 5, another embodiment of the invention is shown which is constructed largely like the one shown in FIG. 3 but with a major difference that the first cartridge slot 11e and the second cartridge slot 11f do not stack over each other but locate at different ends of the circuit board 1c.

Refer now to FIG. 6 for the embodiment of FIG. 5 adopted in a device, in which the circuit board assembly with multiple cartridge slots is housed in a casing 12a. The casing 12a has a first opening 140a corresponding to the first slot opening 110e of the first cartridge slot 11e, and a second opening 140b corresponding to the second slot opening 110f of the second cartridge slot 11f to facilitate cartridges retrieving. Preferably, the casing 12a may have a first dust-guarding lid 14a and a second dust-guarding lid 14b located respectively at the first opening 140a and the second opening 140b for shielding respectively the first slot opening 110e of the first cartridge slot 11e and the second slot opening 110f of the second cartridge slot 11f.

In the present invention, the type or size of the first cartridge slot and the second cartridge slot may be different. For instance, for using on PDAs, the first cartridge slot may be adopted for a Secure Digital Memory Card (SD), and the second cartridge slot may be adopted for a Compact Flash Memory Card (CF). These different configurations and the circuit layouts related on the circuit board and related connections are known in the art, and thus will be omitted herein.

While the discussion set forth above has been focused on both sides of the circuit board, each side thereof having one cartridge slot, it may be applied equally well for embodiments which have more than one cartridge slot located on the same side of the circuit board (as shown in FIG. 2), and with each of the two sides of the circuit board having the cartridge slots located thereon.

While the preferred embodiments of the inventions have been set forth for purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A circuit board assembly with multiple cartridge slots comprising a circuit board which has thereof a first side and a second side opposite to the first side, the first side having at least one first cartridge slot located thereon, and the second side having at least one second cartridge slot located thereon.

2. The circuit board assembly with multiple cartridge slots of claim 1, wherein said first cartridge slot and said second cartridge slot are stacked together but spaced from each other by said circuit board.

3. The circuit board assembly with multiple cartridge slots of claim 1 further having a casing, said first cartridge slot having thereof a first slot opening and said second cartridge slot having thereof a second slot opening, the casing having thereof a first opening and a second opening corresponding respectively to the first slot opening and the second slot opening.

4. The circuit board assembly with multiple cartridge slots of claim 3, wherein said casing has thereof an openable dust-guarding lid engaged with said first opening for shielding said first slot opening.

5. The circuit board assembly with multiple cartridge slots of claim 3, wherein said casing has thereof an openable dust-guarding lid engaged with said second opening for shielding said second slot opening.

6. The circuit board assembly with multiple cartridge slots of claim 3, wherein said first cartridge slot and said second cartridge slot are housed in said casing and are stacked together but spaced from each other by said circuit board.

7. The circuit board assembly with multiple cartridge slots of claim 6 further having an openable dust-guarding lid engaged with said casing for shielding said first opening and said second opening.

8. A circuit board assembly with multiple cartridge slots, comprising:
a circuit board, having thereof a first side and a second side opposite to the first side;
a first cartridge slot, located on the first side and having thereof a first slot opening; and
a second cartridge slot, located on the second side and having thereof a second slot opening.

9. The circuit board assembly with multiple cartridge slots of claim 8, wherein said first cartridge slot and said second cartridge slot are stacked together but spaced from each other by said circuit board, and said first slot opening and said second slot opening being directed towards same direction.

10. The circuit board assembly with multiple cartridge slots of claim 8 further having a casing which has a first opening and a second opening corresponding respectively to said first slot opening and said second slot opening.

11. The circuit board assembly with multiple cartridge slots of claim 10, wherein said casing has an openable dust-guarding lid engaged with said first opening for shielding said first slot opening.

12. The circuit board assembly with multiple cartridge slots of claim 10, wherein said casing has thereof an openable dust-guarding lid engaged with said second opening for shielding said second slot opening.

13. The circuit board assembly with multiple cartridge slots of claim 10, wherein said first cartridge slot and said second cartridge slot are stacked together but spaced from each other by said circuit board, said first slot opening and said second slot opening being directed towards same direction.

14. The circuit board assembly with multiple cartridge slots of claim 13 further having an openable dust-guarding lid engaged with said casing for shielding said first opening and said second opening.
